(19) United States
(12) Patent Application Publication
(10) Pub. No.: US 2026/0221209 A1
(43) Pub. Date: Jul. 30, 2026

(54) MEMORY BUILT-IN SELF-TEST WITH AUTOMATED WRITE TRIM TUNING

(71) Applicant: Siemens Industry Software Inc., Plano, TX (US)

(72) Inventors: Jongsin Yun, Portland, OR (US); Benoit Nadeau-Dostie, Gatineau (CA); Martin Keim, Green Cove Springs, FL (US)

(73) Assignee: Siemens Industry Software Inc., Plano, TX (US)

(21) Appl. No.: 19/148,465

(22) PCT Filed: Mar. 23, 2023
(86) PCT No.: PCT/US2023/016078

§ 371 Date: Jul. 16, 2025

(51) Int. Cl. G11C 29/12; G11C 29/02; G11C 29/14

(52) U.S. Cl. CPC G11C 29/1201; G11C 29/028; G11C 29/14

(57) ABSTRACT

This application discloses a memory device configured to store data using a write voltage having a voltage level corresponding to a write trim. A memory built-in self-test system can prompt the memory device to perform memory write operations to store the data using selected test values for the write trim, determine when the memory device fails to correctly store the data with the write voltages corresponding to each of the selected test values for the write trim, and set the write trim for the memory device based, at least in part, on the determination of failures of the memory device to correctly store the data. The memory built-in self-test system is configured to iteratively select one or more of the test values for the write trim based on the determination of failures of the memory device to correctly store the data.

### TECHNICAL FIELD

This application is generally related to electronic design automation and, more specifically, to built-in self-test with automated write trim tuning.

### BACKGROUND

Non-volatile memory devices, such as Flash, Resistive Random Access Memory (ReRAM), and Magnetoresistive Random Access Memory (MRAM) have become an attractive non-volatile memory solution due to their small size, fast operation speed, and good endurance. For example, MRAM devices can store data in magnetic domains, for example, as a spin polarity of magnets in their free layers. A MRAM device can write data in a magnetic domain by setting the spin polarity of magnets in its free layer, for example, applying a write voltage that induces a spin-polarized current through Magnetic Tunnel Junction (MTJ), which exerts torque on local magnetization in the free layer, often called Spin Torque Transfer (STT).

To read the stored data, the MRAM device can ascertain the spin polarity of the magnets in its free layer relative to a pinned reference layer underneath the corresponding free layer. When the spin polarity is parallel to the pinned reference layer, a resistivity on a reference bit-line (BL) of the MRAM device can be deemed low and thus correspond to a data “0” value. When the spin polarity is perpendicular or anti-parallel to the pinned reference layer, the resistivity on the reference bit-line of the MRAM device can be deemed high and thus correspond to a data “1” value. The MRAM device can include sensing circuitry to detect the resistivity on the reference bit-line of the MRAM device and compare the detected resistivity against a reference resistance to determine whether to deem the detected resistivity as low corresponding to a data “0” value or as high corresponding to a data “1” value.

Many MRAM or other non-volatile memory devices have a narrow range of voltage levels for write voltages that can be utilized during write operations. A write voltage with too low of a voltage level may cause the memory device to be unable to complete a write operation within an operation cycle. Conversely, applying a write voltage having a high supply voltage level may cause some memory cells to have a shorter lifespan due to oxide break down, for example, in the Magnetic Tunnel Junction of an MRAM memory device. These memory devices, due to process variation and differing temperature behavior, often individually perform monotonic full trim value evaluation and then have their voltage level for write voltages for the memory devices tuned after engineering analysis of the results, which consumes time and significant engineering resources.

### SUMMARY

This application discloses a memory device configured to store data using a write voltage having a voltage level corresponding to a write trim. A memory built-in self-test system can prompt the memory device to perform memory write operations to store the data using selected test values for the write trim, determine when the memory device fails to correctly store the data with the write voltages corresponding to each of the selected test values for the write trim, and set the write trim for the memory device based, at least in part, on the determination of failures of the memory device to correctly store the data. The memory built-in self-test system is configured to iteratively select one or more of the test values for the write trim based on the determination of failures of the memory device to correctly store the data. Embodiments will be described below in greater detail.

### DESCRIPTION OF THE DRAWINGS

FIG. 1 illustrates an example memory system including a memory built-in self-test system with automated write trim tuning according to various embodiments.

FIG. 2 illustrates a graph of example read and write characteristics of a magnetoresistive memory device according to various embodiments.

FIG. 3 illustrates a graph of example memory device characteristics with full write trim range and a searchable write trim range according to various embodiments.

FIG. 4 illustrates a flowchart showing an example implementation of an automated write trim tuning process according to various embodiments.

FIG. 5A illustrates a graph showing an example automated binary write trim search in an automated trim tuning process according to various embodiments.

FIG. 5B illustrates a graph showing an example automated linear write trim search in an automated trim tuning process according to various embodiments.

### DETAILED DESCRIPTION

Memory Built-In Self-Test System with Automated Write Trim Tuning

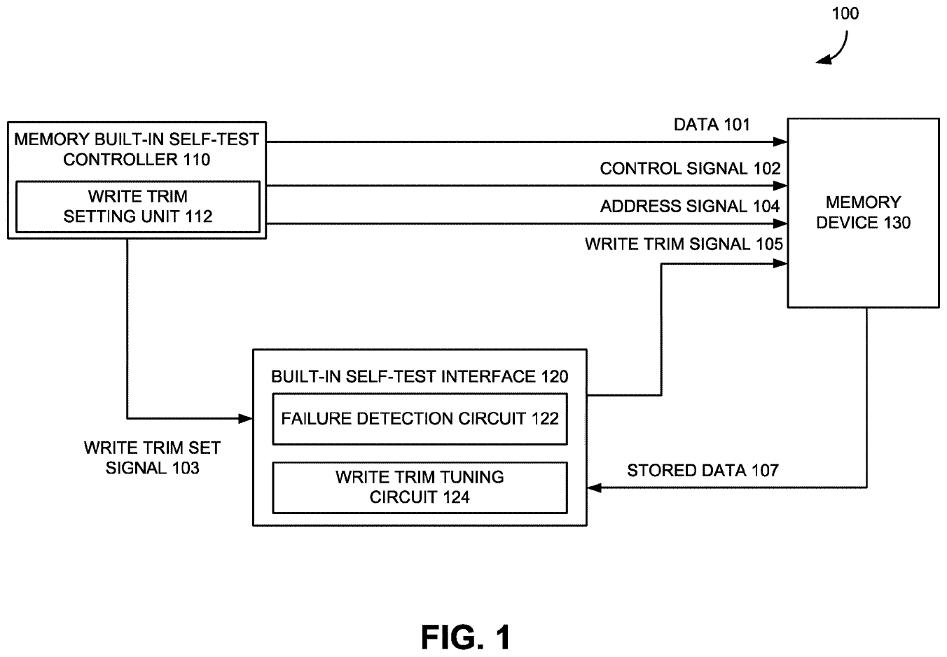

FIG. 1 illustrates an example memory system 100 including a memory built-in self-test with automated write trim tuning according to various embodiments. Referring to FIG. 1, the memory system 100 includes a memory device 130 to store data 101 during data write operations and to output stored data 107 during data read operations. In some embodiments, the memory device 130 can include a Magnetoresistive Random Access Memory (MRAM) to store the data 101 in magnetic domains, for example, as a spin polarity of magnets in a free layer. The Magnetoresistive Random Access Memory can be a Spin Torque Transfer (STT) MRAM device, which can write the data 101 by providing a spin-polarized current through Magnetic Tunnel Junction (MTJ), which exerts torque on local magnetization in the free layer. In other embodiments, the memory device 130 can include other types of Random Access Memory (RAM), such as Dynamic Random Access Memory (DRAM), Static Random Access Memory (SRAM), or the like, or include other types of non-volatile memory, such as Flash memory, Resistive Random Access Memory (ReRAM), or the like.

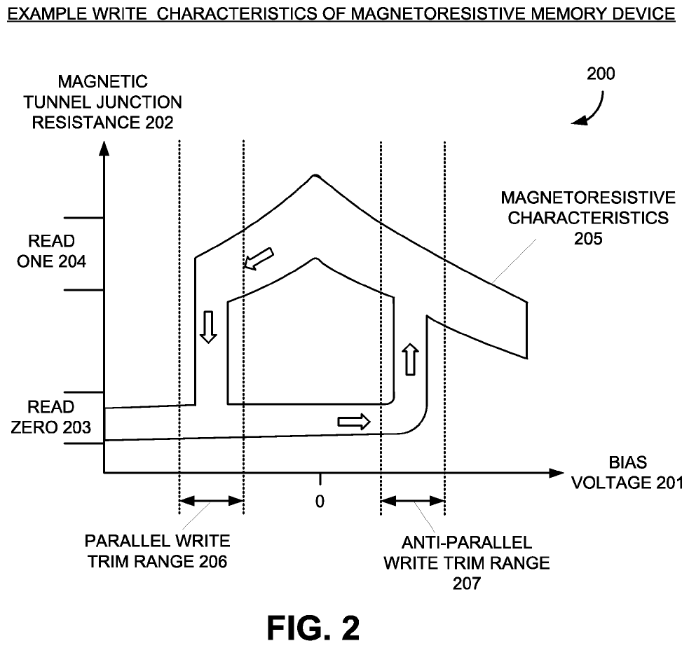

The memory system 100 can include a memory built-in self-test controller 110 to control memory access operations of the memory device 130. The memory built-in self-test controller 110 can generate a control signal 102 and an address signal 104 that, when provided to the memory device 130, can prompt the memory device 130 to perform a memory access operation, such as a data write operation or a data read operation at an address indicated by the address signal 104. When the control signal 102 corresponds to a data write operation, the memory device 130 can store the data 101 from the memory built-in self-test controller 110 at the address indicated by the address signal 104 in response to the control signal 102. The memory device 130 can store the data 101 by applying a write voltage corresponding to a write trim to one or more bit line and source line pair of the memory device 130, for example, which can set a MTJ to parallel state having a low resistance associated with data “0” or set the MTJ to an anti-parallel state having a high resistance associated with data “1.” When the control signal 102 corresponds to a data read operation, the memory device 130 can locate and output the stored data 107 at the address indicated by the address signal 104 in response to the control signal 102. The memory device 130 can read the stored data 107 by sensing an electric value, such as voltage, current, resistance, or the like, associated with a bit line of the memory device 130, and comparing the sensed electrical value against a reference value to determine whether the stored data 107 corresponding to a high data value associated with data “1” or a low data value associated with data “0”. In some embodiments, one or more intermediate data values between may exist between the high data value and the low data value. An example of read and write characteristics of a magnetoresistive memory device is described below with reference to FIG. 2.

FIG. 2 illustrates a graph 200 of example read and write characteristics of a magnetoresistive memory device according to various embodiments. Referring to FIG. 2, the graph 200 has an x-axis corresponding to a bias voltage 201 applied on an accessed bit-line and source-line during write operations of the magnetoresistive memory device and has a y-axis corresponding to magnetic tunnel junction resistances 202 of the magnetoresistive memory device. In this example, when the magnetoresistive memory device receives high enough either forward or reverse bias voltage 201, the magnetic tunnel junction resistances 202 of the magnetoresistive memory device can be altered, for example, in a bias voltage sweep forward and in a reverse direction comprising magnetoresistive characteristics 205 of the magnetoresistive memory device. During write operations to store data with a “0” value, the magnetoresistive memory device can apply a reverse write voltage 201 within a parallel write trim range 206, which alters the magnetic tunnel junction resistance 202 to a lower resistance level. Conversely, during write operations to store data with a “1” value, the magnetoresistive memory device can apply a write voltage 201 within an anti-parallel write trim range 207, which alters the magnetic tunnel junction resistance 202 to a higher resistance level. In some embodiments, the application of write voltages 201 in the memory device can induce a current through the magnetic tunnel junction of the memory device, for example, which can exert torque on local magnetization in the free layer and alter the magnetic tunnel junction resistance to corresponding a stored data “0” value or a stored data “1” value. In this example, the read characteristics can include two groupings, one for bit line resistances associated with reading a stored data “0” value or read zero 203 and another for bit line resistances associated with reading a stored data “1” value or read one 204.

Referring back to FIG. 1, the memory system 100 can include a built-in self-test interface 120 to generate a write trim signal 105 having a value for the write trim used by the memory system 100 during data write operations. The memory built-in self-test controller 110 can include a write trim setting unit 112 to initiate an automated trim feedback process, in part, using a write trim set signal 103, which can allow the built-in self-test interface 120 to set a value for a write trim signal 105. In some embodiments, the value for the write trim can correspond to a voltage level of the write voltage for the memory device 130 to utilize during data write operations. The built-in self-test interface 120 can provide the write trim signal 105 to the memory device 130, which can utilize the value of the write trim signal 105 to adjust the voltage level of the write voltage used to write the data 101 to the memory device 130.

The built-in self-test interface 120 can automatically set the value for the write trim that the memory device 130 can utilize to write the data 101. In some embodiments, the built-in self-test interface 120 can set the value of the write trim using an automated write trim tuning process, for example, by prompting storage of the data 101 using different test values of the write trim via the write trim signal 105, receiving the stored data 107 read from the memory device 130, and then setting the value for the write trim via the write trim signal 105 based on the results of the write operations using the different test values of the write trim.

The built-in self-test interface 120 can perform a memory functional test, which can prompt the memory device 130 to store the data 101 to memory addresses and prompt the memory device 130 to perform read operations for the memory addresses to output the stored data 107. The stored data 107 read from the memory device 130 corresponds to the data 101 received by the memory device 130 and stored to the memory addresses. The built-in self-test interface 120 can include a failure detection circuit 122 to receive the stored data 107 from the memory device 130 and to compare the stored data 107 to the data 101. In some embodiments, the failure detection circuit 122 can compare the stored data 107 read from the memory device 130 to the written data 101 by its type of the data, such as a data “1” or a data “0”. The failure detection circuit 122 can determine when the stored data 107 fails to match the data 101 based on the comparison and accumulate a number of memory addresses corresponding to the determined failures.

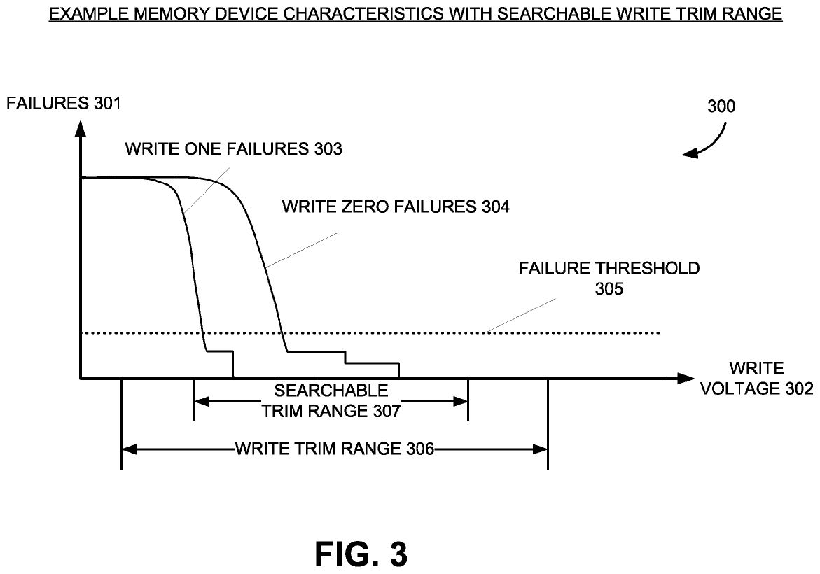

The built-in self-test interface 120 can include a write trim tuning circuit 124 that, in conjunction with the failure detection circuit 122, can collect different test output values by setting the write trim during subsequent writes of the data 101 to the memory device 130. The write trim tuning circuit 124 can generate a write trim signal 105 for the write trim for use in a subsequent write of the test data to the memory device 130. In some embodiments, the write trim tuning circuit 124 can limit the test values of the write trim signal 105 within a write trim range corresponding to a range of values for the write trim of the memory device 130. Embodiments of memory device characteristics and the write trim range will be described below in greater detail with reference to FIG. 3.

The memory built-in self-test controller 110 and the built-in self-test interface 120 can iterate the process of selecting test values for the write trim and reading the test data from the memory until the write trim tuning circuit 124 identifies a setting for the write trim for the type of test data. In some embodiments, the memory built-in self-test controller 110 can select a one type of the data 101 to store to the memory, such as “0 or “1”, or it can select both types of data to test, for example, by performing two consecutive write and read operations using different types of the data for each word and initiate an automated trim tuning process to identify a write trim setting for the type of the data based on its test result.

FIG. 3 illustrates a graph 300 of example memory device characteristics with full write trim range and a searchable write trim range according to various embodiments. Referring to FIG. 3, the graph 300 has an x-axis corresponding to write voltages 302 used by a memory device during data write operations and has a y-axis corresponding to accumulated failures 301 of write operations using the various write voltages 302. The accumulated failures 301 can correspond to a number of instances when the memory device incorrectly stores data using a certain write voltage.

In this example, the graph 300 shows write one failures 303 and write zero failures 304. The write zero failures 304 can correspond to a number of faulty memory device which incorrectly wrote a data value of “0” using the various write voltages 302. The write zero failures 304 show a higher number of failures when utilizing smaller write voltages, and a lower number of failures when using a higher write voltage. The write one failures 303 can correspond to a number of times the memory device incorrectly wrote a data value of “1” using the various write voltages 302. Similar to the write zero failures 304, the write one failures 303 also show a higher number of failures when utilizing smaller write voltages, and a lower number of failures when using a higher write voltage. While this example shows write zero failures 304 as being higher than write one failures 303 at given a write voltage 302, in some examples, the write one failures 303 can be higher than the write zero failures 304, for example, based on an MRAM manufacturing process condition.

An automated write trim tuning circuit implementing an automated write trim tuning value search can set a failure threshold 305 to correspond to a level of failures 301 for the write zero failures 304 and write one failures 303 deemed acceptable for the memory device, for example, a level of failures 301 corresponding to a correctable bit budget of the memory device. The automated write trim tuning circuit can utilize the failure threshold 305 to identify a value for the write trim within the write trim range 306 high enough to enable the memory device to correctly write data to memory, while also suppressing utilization of excessively high write voltages 302 due to potential of lifecycle degradation.

For various reasons, including test time and reliability concerns, the entire write trim range 306 may not always be allowed for an automated write trim tuning search. FIG. 3 shows example searchable trim range 307 where the automated write trim tuning search can modify write trim freely. Since some automated write trim tuning search processes could test write voltages at the extremes of the potential write trim range 306, which can add to overall test time or even damage the memory devices, defining a tunable trim range 307 of available write trim values, the memory device can avoid perform memory write operations with write voltages 302 at certain portions of the write trim range 306.

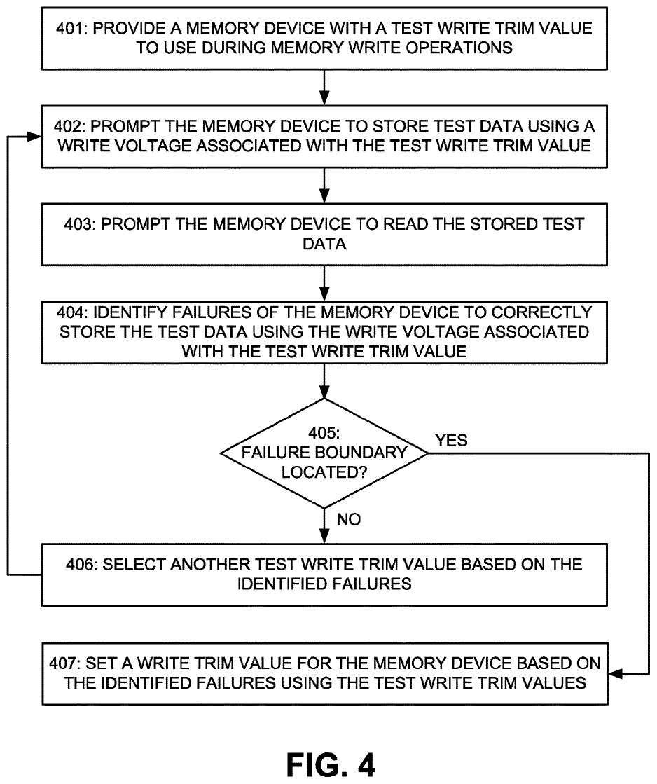

FIG. 4 illustrates a flowchart showing an example implementation of an automated write trim tuning process according to various embodiments. Referring to FIG. 4, in a block 401, a built-in self-test system can provide a memory device with a test write trim value to use during memory write operations. In some embodiments, the built-in self-test system can determine the test write trim value based on a type of automated search being performed to tune the write trim. For example, when performing a linear write trim search process, the built-in self-test system can select a lowest testable write trim value in the write trim range. In other examples, such as when using a binary search process, the built-in self-test system can select a test write trim value towards the middle of the write trim range.

In a block 402, the built-in self-test system can prompt the memory device to store test data using a write voltage associated with the test write trim value. In some embodiments, the built-in self-test system can provide test data having a common data type to a memory device and prompt the memory device to store the test data. The built-in self-test system can generate a control signal to prompt the memory device to perform data write operations with the test data. In some embodiments, the built-in self-test system can write the same data value to memory cells in the memory device, such as all data “1” values or all data “0” values.

In a block 403, the built-in self-test system can prompt the memory device to read the stored test data. The built-in self-test system can generate a control signal to prompt the memory device to perform data read operations. In response to the control signal, the memory device can sense the stored test data and compare the sensed data against a reference value to determine values for the stored test data.

In a block 404, the built-in self-test system can identify a number of failing bits in the memory device associated with the test write trim value. In some embodiments, the built-in self-test system can compare the data read from the memory device against the common data type of the stored data to determine whether the memory device correctly wrote the test data using the test write trim. The built-in self-test system can accumulate the failures of the memory device to correctly write the test data using the test write trim and then compare the accumulated failures against a failure threshold, for example, corresponding to a correctable bit budget of the memory device, to determine a failure result. In some embodiments, the failure results can identify whether the accumulated failures for the test write trim fall above or below the failure threshold. The lowest write trim setting that showed fail bit count fall below the failure threshold is the write trim boundary where BIST can safely set the trim value for the write operation.

In some embodiments, the built-in self-test system can prompt the memory device to perform write operations in the block 402, the read operations in the block 403, and the failure accumulation operation in the block 404 multiple times for a memory address in the memory device. For example, the built-in self-test system can prompt the memory device to write data having a first type to a memory address, read the data stored at the memory address, and accumulate failures based on differences between the written and read data, before prompting the memory device to write data having a second type to the same memory address, read the data stored at the memory address, and accumulate failures based on differences between the written and read data. In some embodiments, the memory device may be prompted to write a data “0” value as the first data type to ensure similar conditions for the subsequent writing data “1”. In this example, the memory device would perform write and read operations for multiple data types before changing memory addresses in order to count failures associated with the multiple data types.

In a block 405, the built-in self-test system can determine whether a failure boundary has been located based on the identified fail count comparison. The built-in self-test system can update the write trim value and repeat the test until it locates the lowest write trim value having met a failure criterion, such as a failure threshold. In some embodiments, the built-in self-test system can locate the failure boundary by an automated binary trim search or an automated linear trim season, which will be described below in greater detail.

When the built-in self-test system determines the failure boundary has not been located for the memory device, in a block 406, the built-in self-test system can select another test with an updated write trim value based on the identified failures and execution can return to the block 402, where the built-in self-test system can prompt the memory device to store test data using a write voltage associated with the newly selected test write trim value. In some embodiments, as will be described below in greater detail, the select another test write trim value can be based on an automated search process, such as a linear search or a binary search.

When the built-in self-test system determines the failure boundary has been located for the memory device, in a block 407, the built-in self-test system can set a final write trim value for the memory device based on the identified failures using the test write trim values. In some embodiments, the built-in self-test system can set the final write trim value few trim steps higher than the identified lowest write trim value with accumulated failures falling below the failure threshold, which may accommodate variation, such as due to temperature effect, lifetime degradation, or the like.

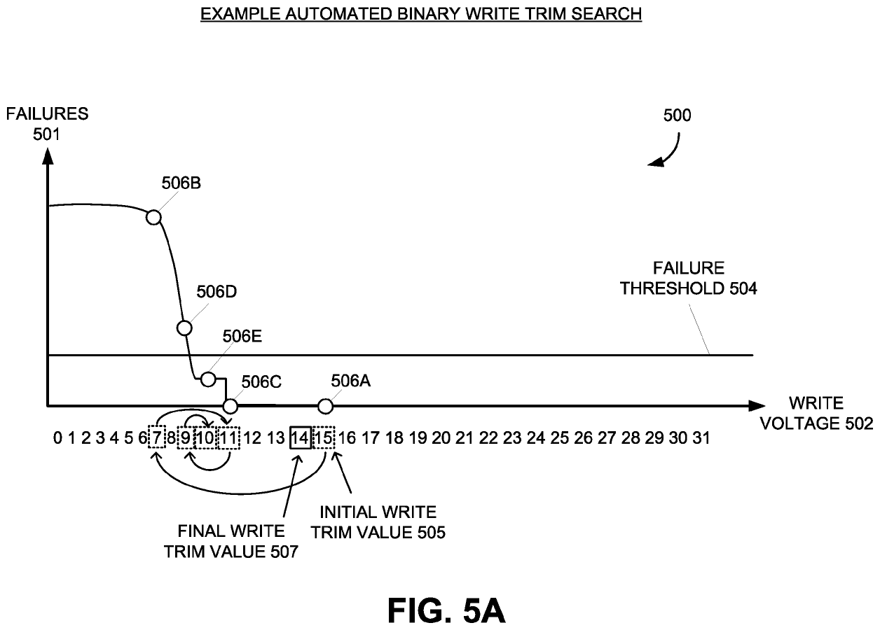

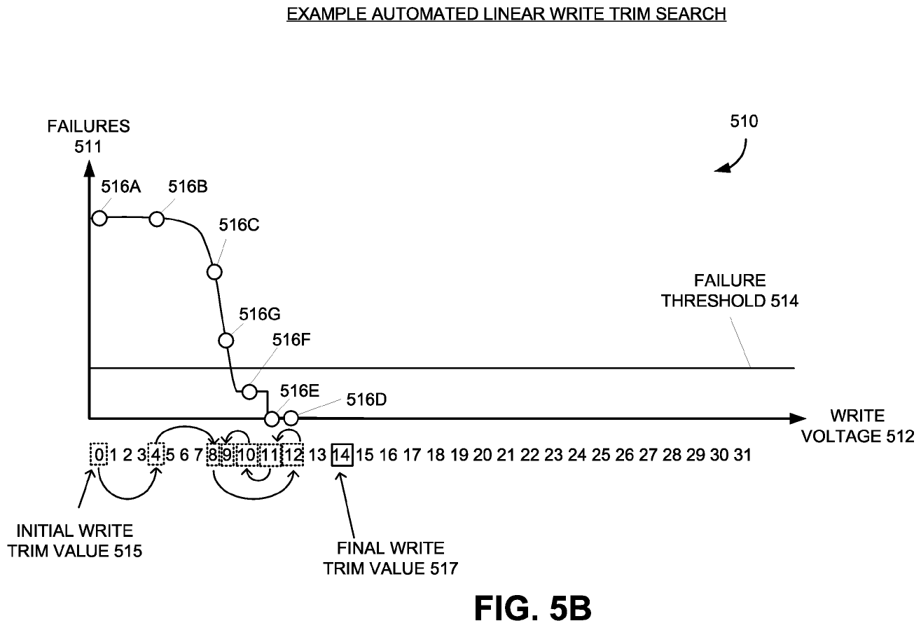

FIG. 5A illustrates a graph 500 showing an example automated binary write trim search in an automated trim tuning process according to various embodiments. Referring to FIG. 5A, the graph 500 has an x-axis corresponding to write voltages 502 used by a memory device during data write operations and has a y-axis corresponding to accumulated failures 501 of write operations using the various write voltages 502. The accumulated failures 501 can correspond to a total number of instances where the memory device incorrectly stores data using a certain write voltage 502.

The automated binary write trim search can select an initial write trim value 505, which can correspond to a middle of a write trim range for the memory device. In this example, the initial write trim value 505 can correspond to the value of 15 or a 5-bit binary value of “01111” in a write trim range spanning from 0 to 31. The memory device can write test data, such as “0” values or “1” values, using a write voltage having a voltage level corresponding to the initial write trim value 505 and then read the test data having been stored by the memory device. The automated binary write trim search can analyze the read test data to determine whether the memory device incorrectly wrote the test data using the write voltage associated with the initial write trim value 505 and then accumulate any determined failures. The automated binary write trim search can determine accumulated failures 506A associated with the write trim value 505 fall below a failure threshold 504, for example, corresponding to a correctable bit budget of the memory device.

Since the accumulated failures 506A associated with the write trim value 505 fall below the failure threshold 504, the automated binary write trim search can determine a failure boundary for the memory device corresponds to a write voltage lower than the write voltage associated with the initial write trim value 505. In some embodiments, rather than test the memory device with a write voltage associated with the initial write trim 505, the automated binary write trim search can determine the initial write trim value 505 falls outside of a searchable trim range on a higher end of the write trim range and deem the failure boundary for the memory device corresponds to a write voltage lower than the write voltage associated with the initial write trim value 505.

The automated binary write trim search can utilize the determination to select a new write trim value in the write trim range having a lower level than the write voltage associated with the initial write trim value 505. In this instance, the automated binary write trim search can select next test trim setting as a middle value of the write trim values in the write trim range falling below the initial write trim value 505, which corresponds to 7 or “00111”. In some embodiments, the automated binary write trim search can set a bit in the binary representation of the write trim value based on the determination of the accumulated failures 506A associated with the write trim value 505 fall below the failure threshold 504. In this example, the most significant bit in the 5-bit binary representation of the write trim value can be set to “0” to all following search tests based on the current determination.

The automated binary write trim search can check whether the selected write trim value falls outside of the searchable write trim range before testing the write trim value. When the write trim value falls inside of the searchable section of the write trim range, the automated binary write trim search can utilize the newly selected write trim value to prompt the memory device to write the test data using a write voltage having a voltage level corresponding to the newly selected write trim value and then read the test data having been stored by the memory device. The automated binary write trim search can analyze the read test data to determine whether the memory device incorrectly wrote the test data using the write voltage associated with the newly selected write trim value and then accumulate any determined failures. The automated binary write trim search can determine accumulated failures 506B associated with the write trim value fall above the failure threshold 504, indicating the voltage level of the write voltage 502 was too low. Similarly, when the newly selected write trim value falls lower than the minimum searchable write trim, the automated binary write trim search can determine the voltage level of the write voltage 502 was too low without memory access to perform the write and read operations and accumulate failure count. The automated binary write trim search can utilize these results to determine the second most significant bit in the 5-bit representation of the write trim value corresponds to a “1” and select yet another write trim value, when previous setting 7 or “00111” was lower than lowest trim range the next write trim value of 11 or “01011” will be set, which is halfway of remaining valid trim range between the write trim value of 7 or “00111” determined to correspond to a write voltage having too low of a voltage level and the initial write trim value 505 of 15 or “01111” determined to correspond to a write voltage having too high of a voltage level.

The automated binary write trim search can reperform this procedure iteratively until a failure boundary for the write trim setting has been identified. For example, the automated binary write trim search can determine write trim value of 11 or “01011” has accumulated failures 506C that fall below the failure threshold 504, setting the third most significant bit to “0” and prompting selection of write trim value of 9 or “01001”. The automated binary write trim search can then determine write trim value of 9 or “01001” has accumulated failures 506D that fall above the failure threshold 504, setting the fourth most significant bit to “1” and prompting selection of write trim value of 10 or “01010”. The automated binary write trim search can perform one last write trim evaluation to determine 5^{th} bit which is least significant bit, for example, determining write trim value of 10 or “01010” has accumulated failures 506E that fall below the failure threshold 504, setting the least significant bit to “0” and identifying the failure boundary with write trim value of 10 or “01010” corresponding to the lowest write voltage with accumulated failures falling below the failure threshold. In some embodiments, the automated binary write trim search can increment the write trim value of 10 or “01010” by a few steps of the write trim to give buffer margin. In this example, the buffer margin corresponded to 4 trim steps, which would provide a final write trim value 507 for the memory device for this test data type. The process can be repeated for other types of test data capable of being stored by the memory device. In some embodiments, the automated binary write trim search can test both data types concurrently, for example, by performing the test of both data types on a memory address of the memory device before incrementing to a new memory address.

FIG. 5B illustrates a graph showing an example automated linear write trim search in an automated trim tuning process according to various embodiments. Referring to FIG. 5B, the graph 510 has an x-axis corresponding to write voltages 512 used by a memory device during data write operations and has a y-axis corresponding to accumulated failures 511 of write operations using the various write voltages 512. The accumulated failures 511 can correspond to a number of instances when the memory device incorrectly stores data using a certain write voltage 512.

The automated linear write trim search can select an initial write trim value 515, which can correspond to a lowest value in a searchable write trim range for the memory device. In this example, the graph 510 shows the initial write trim value being set to a write trim value of 0. The automated linear write trim search can check to determine whether the initial write trim value 515 falls outside of a searchable section of the write trim range. The automated linear write trim search can utilize the initial write trim value 515 to prompt the memory device to write test data, such as “0” values or “1” values, using a write voltage having a voltage level corresponding to the initial write trim value 515 and then read the test data having been stored by the memory device. The automated linear write trim search can analyze the read test data to determine whether the memory device incorrectly wrote the test data using the write voltage associated with the initial write trim value 515 and then accumulate any determined failures. The automated linear write trim search can determine accumulated failures 516A associated with the write trim value fall above the failure threshold 514, indicating the voltage level of the write voltage 512 was too low.

Since the accumulated failures 516A associated with the write trim value 505 fall above the failure threshold 514, the automated linear write trim search can determine a failure boundary for the memory device corresponds to a write voltage higher than the write voltage associated with the initial write trim value 515. The automated linear write trim search can utilize the determination to select a new write trim value in the write trim range having a higher level than the write voltage associated with the initial write trim value 515. In this instance, the automated linear write trim search can increase the write trim value to 4 steps higher in the write trim range than the initial write trim value 515, which corresponds to 4 or “00100”.

The automated linear write trim search can check to determine whether the newly selected write trim value of 4 or “00100” falls outside of the searchable section of the write trim range. When the newly selected write trim value falls inside of the searchable section of the write trim range, the automated linear write trim search can utilize the newly selected write trim value to prompt the memory device to write the test data using a write voltage having a voltage level corresponding to the newly selected write trim value and then read the test data having been stored by the memory device. The automated linear write trim search can analyze the read test data to determine whether the memory device incorrectly wrote the test data using the write voltage associated with the newly selected write trim value and then accumulate the number of any determined failures. The automated linear write trim search can determine accumulated failures 516B associated with the write trim value fall above the failure threshold 514, indicating the voltage level of the write voltage 512 at trim step 4 or “00100” was too low. Similarly, when the newly selected write trim value falls higher trim setting than the predefined maximum searchable section of the write trim range, the automated linear write trim search can determine the voltage level of the write voltage 512 was too high without having to perform the write and read operations and accumulate failures. The automated linear write trim search can utilize these results to select yet another write trim value.

The automated linear write trim search can reperform this procedure iteratively until a failure boundary for the write trim range has been identified. For example, the automated linear write trim search can determine write trim value of 8 has accumulated failures 516C that again fall above the failure threshold 514, prompting selection of write trim value 4 more values higher. Write trim will be increased 4 more value until accumulated failures 511 falls below fail threshold 514. The automated linear write trim search can then determine write trim value of 12 has accumulated failures 516D that fall below the failure threshold 514, prompting decremental trim by selection of write trim value of one value at a time. The automated linear write trim search can then determine write trim value of 11 has accumulated failures 516E that fall below the failure threshold 514, prompting decremental selection of write trim value will continue one value at a time until accumulated failures 511 falls above fail threshold 514. The automated linear write trim search can then determine write trim value of 10 has accumulated failures 516F that fall below the failure threshold 514, prompting selection of write trim value of one value lower. The automated linear write trim search can perform one last write trim evaluation, for example, determining write trim value of 9 has accumulated failures 516G that fall above the failure threshold 514, identifying the failure boundary with write trim value of 10 corresponding to the lowest write voltage with accumulated failures falling below the failure threshold. In some embodiments, the automated linear write trim search can increment the write trim value of 10 or “01010” by a buffer amount, in this instance, 4 values higher, which would provide a final write trim value of 517 for the memory device for this test data type. The process can be repeated for other types of test data capable of being stored by the memory device. In some embodiments, when a prompted write trim value is higher than maximum searchable trim value, the write trim value will be decreased until the write trim value falls inside of the searchable write trim range without having to perform the memory operations, to accumulate failure counts, and compare the accumulated failure counts with the fail threshold. The write trim value can further decrease until accumulated failures corresponding to the write trim values fall above fail threshold 514, and set the write trim value as corresponding to 1 step higher than tested trim value where accumulated failures falls above fail threshold 514.

The system and apparatus described above may use dedicated processor systems, micro controllers, programmable logic devices, microprocessors, or any combination thereof, to perform some or all of the operations described herein. Some of the operations described above may be implemented in software and other operations may be implemented in hardware. Any of the operations, processes, and/or methods described herein may be performed by an apparatus, a device, and/or a system substantially similar to those as described herein and with reference to the illustrated figures.

The processing device may execute instructions or “code” stored in memory. The memory may store data as well. The processing device may include, but may not be limited to, an analog processor, a digital processor, a microprocessor, a multi-core processor, a processor array, a network processor, or the like. The processing device may be part of an integrated control system or system manager, or may be provided as a portable electronic device configured to interface with a networked system either locally or remotely via wireless transmission.

The processor memory may be integrated together with the processing device, for example RAM or FLASH memory disposed within an integrated circuit microprocessor or the like. In other examples, the memory may comprise an independent device, such as an external disk drive, a storage array, a portable FLASH key fob, or the like. The memory and processing device may be operatively coupled together, or in communication with each other, for example by an I/O port, a network connection, or the like, and the processing device may read a file stored on the memory. Associated memory may be “read only” by design (ROM) by virtue of permission settings, or not. Other examples of memory may include, but may not be limited to, WORM, EPROM, EEPROM, FLASH, or the like, which may be implemented in solid state semiconductor devices. Other memories may comprise moving parts, such as a known rotating disk drive. All such memories may be “machine-readable” and may be readable by a processing device.

Operating instructions or commands may be implemented or embodied in tangible forms of stored computer software (also known as “computer program” or “code”). Programs, or code, may be stored in a digital memory and may be read by the processing device. “Computer-readable storage medium” (or alternatively, “machine-readable storage medium”) may include all of the foregoing types of memory, as well as new technologies of the future, as long as the memory may be capable of storing digital information in the nature of a computer program or other data, at least temporarily, and as long at the stored information may be “read” by an appropriate processing device. The term “computer-readable” may not be limited to the historical usage of “computer” to imply a complete mainframe, mini-computer, desktop or even laptop computer. Rather, “computer-readable” may comprise storage medium that may be readable by a processor, a processing device, or any computing system. Such media may be any available media that may be locally and/or remotely accessible by a computer or a processor, and may include volatile and non-volatile media, and removable and non-removable media, or any combination thereof.

A program stored in a computer-readable storage medium may comprise a computer program product. For example, a storage medium may be used as a convenient means to store or transport a computer program. For the sake of convenience, the operations may be described as various interconnected or coupled functional blocks or diagrams. However, there may be cases where these functional blocks or diagrams may be equivalently aggregated into a single logic device, program or operation with unclear boundaries.

### CONCLUSION

While the application describes specific examples of carrying out embodiments of the invention, those skilled in the art will appreciate that there are numerous variations and permutations of the above described systems and techniques that fall within the spirit and scope of the invention as set forth in the appended claims. For example, while specific terminology has been employed above to refer to electronic design automation processes, it should be appreciated that various examples of the invention may be implemented using any desired combination of electronic design automation processes.

One of skill in the art will also recognize that the concepts taught herein can be tailored to a particular application in many other ways. In particular, those skilled in the art will recognize that the illustrated examples are but one of many alternative implementations that will become apparent upon reading this disclosure.

Although the specification may refer to “an”, “one”, “another”, or “some” example(s) in several locations, this does not necessarily mean that each such reference is to the same example(s), or that the feature only applies to a single example.

1. A system comprising:
a memory device configured to store data using a write voltage having a voltage level corresponding to a write trim; and
a memory built-in self-test system configured to prompt the memory device to selectively perform memory write operations to store the data using selected test values for the write trim in a write trim range based on whether the selected test values for the write trim fall outside of a searchable section of the write trim range, determine when the memory device fails to correctly store the data with the write voltages corresponding to each of the selected test values for the write trim, and set the write trim for the memory device based, at least in part, on the determination of failures of the memory device to correctly store the data, wherein the memory built-in self-test system is configured to iteratively select one or more of the test values for the write trim based, at least in part, on the determination of failures of the memory device to correctly store the data.

2. The system of claim 1, wherein the memory built-in self-test system is configured to skip prompting the memory device to perform the memory write operations for the selected test values that fall outside of the searchable section of the write trim range, and deem the memory device as having failed to correctly store the data for the selected test values that fall outside of the searchable section of the write trim range.

3. The system of claim 1, wherein the memory built-in self-test system is configured to iteratively select the test values for the write trim using a binary search based, at least in part, on the failures of the memory device to correctly store the data, and set the write trim for the memory device based, at least in part, on the binary search of the test write trims.

4. The system of claim 1, wherein the memory built-in self-test system is configured to iteratively select the test values for the write trim using a binary search based, at least in part, on the failures of the memory device to correctly store the data, and set the write trim for the memory device based, at least in part, on the linear search of the test write trims.

5. The system of claim 1, wherein the memory built-in self-test system is configured to determine when the memory device fails to correctly store the data by reading the stored data from the memory device and comparing the values of the stored data against an expected value to identify the failures, and wherein the memory built-in self-test system is configured to accumulate the failures of the memory device to correctly write the data for each of the write voltages, compare the accumulated failures to a failure threshold, and set bits of the write trim based, at least in part, on the comparisons of the accumulated failures to the failure threshold.

6. The system of claim 5, wherein the failure threshold corresponds to a correctable bit budget of the memory device.

7. The system of claim 1, wherein the memory built-in self-test system is configured to iteratively select one or more of the test values for the write trim based, at least in part, on the determination of failures of the memory device to correctly store the data having different data types for each memory address of the memory device, and set the write trim for the memory device based, at least in part, on the determination of failures of the memory device to correctly store the data from both of the data types.

8. A method comprising:
prompting, by a memory built-in self-test system, a memory device to selectively perform memory write operations to store the data using selected test values for the write trim in a write trim range based on whether the selected test values for the write trim fall outside of a searchable section of the write trim range;
determining, by the memory built-in self-test system, when the memory device fails to correctly store the data with the write voltages corresponding to each of the selected test values for the write trim, wherein the memory built-in self-test system is configured to iteratively select one or more of the test values for the write trim based, at least in part, on the determination of failures of the memory device to correctly store the data, and
setting, by the memory built-in self-test system, the write trim for the memory device based, at least in part, on the determination of failures of the memory device to correctly store the data.

9. The method of claim 8, further comprising:
skipping, by the memory built-in self-test system, prompting the memory device to perform the memory write operations for the selected test values that fall outside of the searchable section of the write trim range, and
deeming, by the memory built-in self-test system, the memory device as having failed to correctly store the data for the selected test values that fall outside of the searchable section of the write trim range.

10. The method of claim 8, wherein the memory built-in self-test system is configured to iteratively select the test values for the write trim using a binary search based, at least in part, on the failures of the memory device to correctly store the data, and set the write trim for the memory device based, at least in part, on the binary search of the test write trims.

11. The method of claim 8, wherein the memory built-in self-test system is configured to select the test values for the write trim using a binary search based, at least in part, on the failures of the memory device to correctly store the data, and set the write trim for the memory device based, at least in part, on the linear search of the test write trims.

12. The method of claim 8, wherein determining when the memory device fails to correctly store the data further comprises reading the stored data from the memory device and comparing the values of the stored data against an expected value to identify the failures, and further comprising:
accumulating, by the memory built-in self-test system, the failures of the memory device to correctly write the data for each of the write voltages;
comparing, by the memory built-in self-test system, the accumulated failures to a failure threshold; and
setting, by the memory built-in self-test system, bits of the write trim based, at least in part, on the comparisons of the accumulated failures to the failure threshold.

13. The method of claim 12, wherein the failure threshold corresponds to a correctable bit budget of the memory device.

14. The method of claim 8, wherein iteratively selecting one or more of the test values for the write trim is based, at least in part, on the determination of failures of the memory device to correctly store the data having different data types for each memory address of the memory device, and wherein setting the write trim for the memory device is based, at least in part, on the determination of failures of the memory device to correctly store the data from both of the data types.

15. An apparatus comprising:
a memory built-in self-test controller configured to prompt the memory device to selectively perform memory write operations to store the data using selected test values for the write trim in a write trim range based on whether the selected test values for the write trim fall outside of a searchable section of the write trim range; and
a write trim tuning circuit configured to determine when the memory device fails to correctly store the data with the write voltages corresponding to each of the selected test values for the write trim, and set the write trim for the memory device based, at least in part, on the determination of failures of the memory device to correctly store the data, wherein the write trim tuning circuit is configured to iteratively select one or more of the test values for the write trim based, at least in part, on the determination of failures of the memory device to correctly store the data.

16. The apparatus of claim 15, wherein the write trim tuning circuit is configured to skip prompting the memory device to perform the memory write operations for the selected test values that fall outside of the searchable section of the write trim range, and deem the memory device as having failed to correctly store the data for the selected test values that fall outside of the searchable section of the write trim range.

17. The apparatus of claim 15, wherein the write trim tuning circuit is configured to iteratively select the test values for the write trim using a binary search based, at least in part, on the failures of the memory device to correctly store the data, and set the write trim for the memory device based, at least in part, on the binary search of the test write trims.

18. The apparatus of claim 15, wherein the write trim tuning circuit is configured to iteratively select the test values for the write trim using a binary search based, at least in part, on the failures of the memory device to correctly store the data, and set the write trim for the memory device based, at least in part, on the linear search of the test write trims.

19. The apparatus of claim 15, wherein the write trim tuning circuit is configured to determine when the memory device fails to correctly store the data by reading the stored data from the memory device and comparing the values of the stored data against an expected value to identify the failures.

20. The apparatus of claim 18, wherein the write trim tuning circuit is configured to accumulate the failures of the memory device to correctly write the data for each of the write voltages, compare the accumulated failures to a failure threshold, and set bits of the write trim based, at least in part, on the comparisons of the accumulated failures to the failure threshold.
